(19) United States
(12) Patent Application Publication
(10) Pub. No.: US 2006/0159948 A1
(43) Pub. Date: Jul. 20, 2006

(54) Resin product with plating film and manufacturing method thereof

(75) Inventors: Yosuke Maruoka, Aichi-ken (JP); Yasuhiko Ogisu, Aichi-ken (JP); Hiroshi Watarai, Aichi-ken (JP); Seitaro Taki, Aichi-ken (JP)

Correspondence Address: POSZ LAW GROUP, PLC, 12040 SOUTH LAKES DRIVE, SUITE 101, RESTON, VA, 20191, US

(73) Assignee: TOYODA GOSEI CO., LTD., Aichi-ken (JP)

(21) Appl. No.: 11/314,086

(22) Filed: Dec. 22, 2005

(30) Foreign Application Priority Data
Dec. 28, 2004 (JP) 2004-380917

(51) Int. Cl. C23C 16/00; C03C 27/02; C03C 27/04

(52) U.S. Cl. 428/633; 427/223; 427/299; 427/248.1; 428/632

(57) ABSTRACT

After a silicatizing flame, a titanium oxidizing flame, or an aluminum oxidizing flame is blown together with an oxidizing flame onto the surface of a resin base material to perform surface modification treatment, dry plating or wet plating is performed on the surface of the resin base material to thereby form a plating film. In the surface modification, in the case of the silicatizing flame, for example, silanol groups are imparted to the surface of the resin base material as polar groups necessary for obtaining adhesion to the plating film.

### BACKGROUND OF THE INVENTION

1. Field of the Invention

The present invention relates to a resin product with a plating film and a manufacturing method thereof.

2. Related Art

Many kinds of resins as they are are weak in the adhesion of a plating film, so that pretreatment needs to be provided on the surface of a resin base material before performing plating so as to ensure the adhesion. For example, before performing dry plating (vapor deposition, sputtering, etc.), a base coat layer (primer layer) is frequently formed so as to ensure the adhesion by imparting polar groups to the surface of the resin base material (e.g., JP-A-6-122777). In the case where wet plating is performed (electroless plating, electroplating, etc.), etching treatment using chromic acid is frequently provided so as to secure the amount of adhesion by an anchor effect by coarsening the surface of the resin base material (e.g., JP-A-2003-41375). In addition, among wet plating processes, in the case of silver mirror reaction which is one kind of electroless plating, there are cases where the aforementioned base coat layer is provided.

However, the base coat layer as a pretreatment is difficult to form uniformly, and there is the problem of the so-called graininess defect (graininess appears on the plated surface due to small projections formed on the base coat layer), and there are cases where substantial trouble, time, and cost are incurred. In addition, etching treatment using chromic acid as a pretreatment presents an environmental problem since hexavalent chromium is an environmental load substance, so that a substitute to other treatment is desired.

### SUMMARY OF THE INVENTION

Accordingly, an object of the invention is to obtain a resin molded product with a plating film which is capable of ensuring the adhesion of the plating film and of reducing graininess defects by a novel pretreatment which can overcome the above-described problems and reduce the trouble, time, and cost, and presents no environmental problem.

Accordingly, as a result of conducting various studies on novel pretreatments substituting the base coat layer and etching treatment, the present inventor took note of a silicatizing flame which has been developed in the fields of “bonding, printing, and painting” (JP-A-2003-238710). As a result of studying this treatment for the first time as a pretreatment for plating, the present inventor devised the invention after obtaining good results.

Namely, the invention has the following features:

(1) A resin product with a plating film comprising: a resin base material subjected to surface modification treatment by blowing one of a silicatizing flame, a titanium oxidizing flame, and an aluminum oxidizing flame onto a surface of a resin base material; and a plating film formed on the surface of the resin base material after the surface modification treatment, by performing one of dry plating and wet plating.

(2) A method of manufacturing a resin product with a plating film, comprising the steps of: subjecting a resin base material to surface modification treatment by blowing one of a silicatizing flame, a titanium oxidizing flame, and an aluminum oxidizing flame onto a surface of a resin base material; and forming a plating film on the surface of the resin base material by performing one of dry plating and wet plating.

<Resin Base Material>

Here, the kinds of resin of the resin base material are not particularly limited, but it is possible to cite the following thermoplastic resins and thermosetting resins by way of example:

Thermoplastic resins; It is possible to cite by way of example at least one thermoplastic resin selected from the group consisting of a polyethylene resin, polypropylene resin, ABS (acrylonitrile butadiene styrene) resin, AES (acrylonitrile-EPDM-styrene) resin, AAS (alkyl aryl sulfonate) resin, polyacetal resin, polymethylpentene resin, polyester resin, polycarbonate resin, polyether sulfone resin, methacrylic resin, polyacrylic resin, polyether ether ketone resin, polyimide resin, polysulfone resin, polystyrene resin, polyamide resin, polyphenylenesulfide resin, polyvinyl chloride resin, ethylene-tetrafluoroethylene copolymer, polyvinyl fluoride resin, tetrafluoroethylene-perfluoroether copolymer, tetrafluoroethylene-hexafluoropropylene copolymer, polytetrafluoroethylene resin, polyvinylidene fluoride resin, polytrifluorochloroethylene resin, and ethylene-trifluorochloroethylene copolymer.

Thermosetting resins: It is possible to cite by way of example at least one thermosetting resin selected from the group consisting of an epoxy resin, phenolic resin, cyanate resin, urea resin, and guanamine resin.

<Silicatizing Flame, Titanium Oxidizing flame, or Aluminum Oxidizing Flame>

The silicatizing flame, the titanium oxidizing flame, or the aluminum oxidizing flame is a flame of a combustible gas including a modifier compound containing a silane atom, a titan atom, or an aluminum atom. The silicatizing flame, the titanium oxidizing flame, or the aluminum oxidizing flame is preferably blown together with an oxidizing flame since the treatment can be done only in one process; however, the silicatizing flame, the titanium oxidizing flame, or the aluminum oxidizing flame may be blown as an ensuing process after blowing the oxidizing flame separately.

The boiling point of this modifier compound is preferably 10 to 100° C. Namely, if the boiling point of the modifier compound is limited to a predetermined range, the modifier compound vaporizes appropriately and mixes with the gas uniformly and speedily, thereby facilitating complete combustion. As a result, the surface modification of the resin base material is carried out uniformly.

This modifier compound is preferably at least one compound selected from the group consisting of an alkylsilane compound, alkoxysilane compound, alkyltitanium compound, alkoxytitanium compound, alkylaluminum compound, and alkoxyaluminum compound. By using such a modifier compound, the adhesion of the plating film becomes strong, and its persistence becomes high.

In the surface modification by the blowing of the silicatizing flame, the titanium oxidizing flame, or the aluminumoxidizing flame, in the case of the silicatizing flame, for example, silanol groups, titanium hydroxide or aluminum hydroxide is imparted in activated state to the surface of the resin base material as polar groups necessary for obtaining adhesion to the plating film.

In addition, these treatments are preferably carried out under the following conditions (above-mentioned JP-A-2003-238710).

1. If the total amount of fuel gas is set to be 100 mol %, the content of the modifier compound in the fuel gas is preferably set to a value in the range of 1×10⁻¹⁰ to 10 mol %.

2. After the modifier compound is heated and set in a gaseous state, the modifier compound is preferably burned.

3. The modifier compound is preferably made into a fuel gas by being mixed with an airflow. Also, the modifier compound is preferably mixed with the air flow by using a carrier gas.

4. The flame temperature is preferably set to a value in the range of 500 to 1,500° C.

5. The flame treatment time is preferably set to a value in the range of 0.1 to 100 sec.

<Dry Plating>

The dry plating which is performed after the surface modification treatment is not particularly limited, but it is possible to cite vacuum deposition, sputtering, ion plating, and the like.

<Wet Plating>

As the wet plating which is performed after the surface modification treatment, it is possible to cite by way of example electroplating, electroless plating, and the like. Electroless plating includes silver mirror reaction.

According to the resin product with a plating film and a manufacturing method thereof in accordance with the invention, it is possible to ensure the adhesion of the plating film and reduce graininess defects by a novel pretreatment which can reduce the trouble, time, and cost, and presents no environmental problem.

### DETAILED DESCRIPTION OF THE PREFERRED EMBODIMENTS

After a silicatizing flame, a titanium oxidizing flame, or an aluminum oxidizing flame is blown together with an oxidizing flame onto the surface of a resin base material to perform surface modification treatment, dry plating or wet plating is performed on the surface of the resin base material to thereby form a plating film.

### EXAMPLES

A description will be given of examples in which the present invention was embodied.

First, Table 1 shows Examples 1 and 2 and Comparative Examples 1 and 2 in which silver mirror reaction, i.e., a kind of wet plating, was performed. Example 1 is an example in which after a silicatizing flame was blown together with an oxidizing flame onto a plate-shaped ASS resin base material of 10 cm×10 cm, silver mirror reaction was performed through predetermined processes listed in Table 1, thereby forming a silver plating film. The details of the processes listed in Table 1 are shown in Table 3.

Namely, the silicatizing flame and the oxidizing flame were provided from the fuel gas shown in Table 3. The flame temperature was about 1300° C. A treatment surface for plating of the plate-shaped ABS resin base material was exposed to the flames in 0.5 second.

After that, the catalyst was imparted on the treatment surface using the chemicals as shown in Table 3. PdSn compounds was served as the catalyst. Treatment temperature was 25° C.

Activation process was performed to the treatment surface under the condition as shown in Table 3. More specifically, in this activation process, Sn atoms in the PdSn compounds were removed so that Pd atoms remained on the treatment surface were brought in activated state. Then, silver mirror reaction was performed using the solutions A and B as shown in Table 3. In this example the solutions A and B were simultaneously blown by a double-headed gun or a concentric gun under the treatment temperature of 25° C., so that a silver plating film was formed on the resin base material. Then the resin base material was rinsed with industrial water at 25° C.

Example 2 was carried out in the same way as Example 1 except that a plate-shaped PP (polypropylene) resin base material of 10 cm×10 cm was used. Comparative Example 1 was carried out in the same way as Example 1 except that the blowing of the silicatizing flame was not performed. Comparative Example 2 was carried out in the same way as Example 1 except that etching treatment using hexavalent chromium was provided instead of the blowing of the silicatizing flame.

Next, Table 2 shows Example 3 and Comparative Example 3 in which electroless plating, i.e., a kind of wet plating, was performed. Example 3 is an example in which after the silicatizing flame was blown together with the oxidizing flame onto an ABS resin base material, electroless nickel plating was performed through the predetermined processes listed in Table 2, thereby forming a nickel plating film. The details of these processes listed in Table 2 are shown in Table 4.

Namely, the silicatizing flame and the oxidizing flame were provided from the fuel gas shown in Table 4. The flame temperature was about 1300° C. A treatment surface for plating of the ABS resin base material was exposed to the flames in 0.5 second.

Next, the chrome etching was performed to the treatment surface using the chemicals as shown in Table 4. The resin material was immersed in the chemical solution under the treatment temperature of 65° C. for 10 minutes. Then, the acid neutralization was performed under the condition as shown in Table 4. The resin material was immersed in the chemical solution as shown in Table 4 under the treatment temperature of 25° C. for 5 minutes.

After that, the catalyst was imparted on the treatment surface by immersion in the chemicals as shown in Table 4 under the temperature of 25° C. for 3 minutes.

Activation process was performed to the treatment surface under the condition as shown in Table 4. The resin material was immersed in concentrated sulfuric solution under the temperature of 30° C. for 2 minutes. Then, electroless Ni plating was performed in a TMP chemical nickel bath under the temperature of 30° C. for 10 minutes. A nickel plating film was formed on the resin base material.

Comparative Example 3 was carried out in the same way as Example 3 except that etching treatment using hexavalent chromium was provided instead of the blowing of the silicatizing flame.

Table 2 further shows Example 4 and Comparative Example 4 in which vacuum deposition, i.e., a kind of dry plating, was performed. Example 4 is an example in which after the silicatizing flame was blown together with the oxidizing flame onto an ABS resin base material, an indium plating film was formed by performing indium vacuum deposition, The details of these processes listed in Table 2 are shown in Table 5.

Namely, the silicatizing flame and the oxidizing flame were provided from the fuel gas shown in Table 5. The flame temperature was about 1300° C. A treatment surface for plating of the ABS resin base material was exposed to the flames in 0.5 second.

After that vacuum deposition was conducted on the treatment surface. Indium was deposited on the treatment surface of the ABS resin base material under a degree of vacuum of 5.0 10⁻⁴ Pa to form an indium plating film. Deposition rate was in a range of 0.3 to 0.5 nm/sec. The film thickness was approximately 1000 Å.

Comparative Example 4 was carried out in the same way as Example 4 except that the blowing of the silicatizing flame was not performed.

Table 3 shows the details of silver mirror reaction and its preliminary processes listed in Table 1.

Table 4 shows the details of electroless plating and its preliminary processes listed in Table 2.

Table 5 shows the details of vacuum deposition and its preliminary process listed in Table 2.

With respect to the above Examples 1 to 4 and Comparative Examples 1 to 4, the following two tests were conducted to evaluate the adhesion of the plating film.

(1) Grid Pattern Taping Test

A grid pattern taping test was conducted in accordance with JIS G 0202. Specifically, this is a method in which 100 meshes (10×10 meshes) of a grid pattern with a 2 mm width are cut on the coated surface with a cutter knife, a cellophane tape is adhered thereto and is forcibly peeled off, and the number of peeled-off meshes among the 100-mesh grid pattern is determined. For example, “0/100-10” means that taping was effected 10 times, and 0 mesh was peeled off in the grid pattern of 100 meshes (i.e., no meshes are peeled off in this case)

(2) Pull-Off Test

A pull-off test was conducted in accordance with Section 8.7 of JIS K 5400. Specifically, this is a method in which a pulling jig is adhered to a coated surface with an epoxy-based adhesive, the jig is pulled perpendicularly to the coated surface, and a load at which the coated surface is fractured from the coated object is determined. In the measurement, an ericometer (made by Densokusha Co. Ltd.) was used. In addition, the measurement was made twice, and averages were obtained.

These test results are shown in Tables 1 and 2 above. Comparative Example 1 showed remarkably low peel strength in both the grid pattern taping test and the pull-off test, and although Comparative Example 2 showed no peeling-off in the grid pattern taping test, its pull-off peel strength was relatively low. In Examples 1 and 2, on the other hand, peel strength was sufficiently high in both the grid pattern taping test and the pull-off test, and the adhesion of a silver plating film formed by silver mirror reaction was ensured. Meanwhile, Comparative Example 3 showed no peeling-off in the grid pattern taping test, but its pull-off peel strength was low, whereas Example 3 showed sufficiently high peel strength in both the grid pattern taping test and the pull-off test, and the adhesion of a nickel plating film formed by electroless plating was ensured. Comparative Example 4 showed remarkably low peel strength in both the grid pattern taping test and the pull-off test, whereas Example 4 showed sufficiently high peel strength in both the grid pattern taping test and the pull-off test, and the adhesion of an indium plating film formed by vacuum deposition was ensured. In addition, no graininess defect was noted in any one of Examples 1 to 4.

It should be noted that the invention is not limited to the above-described embodiment, and may be embodied by making alterations or modifications, as required, within the scope that does not depart from the gist of the invention.

[image]

[image]

TABLE 3

| | | |
|---|---|---|
| SILICATIZING FLAME | FUEL GAS: | TETRAMETHYLSILANE AND TETRAMETHOXYSILANE |
| (PLUS OXIDIZING FLAME) | | (1% OR LESS CONTAINED IN PROPANE GAS) |
| | FLAME TEMPERATURE: | 1300° C. |
| | TREATMENT TIME: | 0.5 sec |
| IMPARTING OF CATALYST | CHEMICALS: | OPC-90 CATALYST (OKUNO CHEMICAL INDUSTRIES CO., LTD.) |
| | | 40 ml/L |
| | | 35% HYDROCHLORIC ACID 200 ml/L |
| | TEMPERATURE: | 25° C. |
| ACTIVATION | CHEMICAL: | OPC-500 ACCELERATOR (OKUNO CHEMICAL INDUSTRIES CO., LTD.) |
| | | 50 ml/L |
| | TEMPERATURE: | 25° C. |
| SILVER MIRROR REACTION | CHEMICALS: | |
| | SILVER MIRROR SOLUTION A: | AMMONIACAL SILVER NITRATE SOLUTION |
| | | (6.0 g/L AS Ag) |
| | SILVER MIRROR SOLUTION B: | HYDRAZINE HYDRATE 5.0 ml/L |
| | METHOD: | SOLUTION A AND SOLUTION B ARE SIMULTANEOUSLY BLOWN |
| | | BY A DOUBLE-HEADED GUN OR A CONCENTRIC GUN. |
| | TEMPERATURE: | 25° C. |
| RINSING | CHEMICAL: | INDUSTRIAL WATER |
| | TEMPERATURE: | 25° C. |

TABLE 4

| | | |
|---|---|---|
| SILICATIZING FLAME | FUEL GAS: | TETRAMETHYLSILANE AND TETRAMETHOXYSILANE |
| (PLUS OXIDIZING | | (1% OR LESS CONTAINED IN PROPANE GAS) |
| FLAME) | FLAME TEMPERATURE: | 1300° C. |
| | TREATMENT TIME: | 0.5 sec |
| CHROME ETCHING | CHEMICALS: | CHROMIC ACID ANHYDRIDE 400 g/L |
| | | CONCENTRATED SULFURIC ACID 400 g/L |
| | TEMPERATURE: | 65° C. |
| | IMMERSION TIME: | 10 MINUTES |
| ACID NEUTRALIZATION | CHEMICAL: | CONCENTRATED HYDROCHLORIC ACID 50 m/L |
| | TEMPERATURE: | 25° C. |
| | IMMERSION TIME: | 5 MINUTES |
| IMPARTING OF CATALYST | CHEMICALS: | CATALYST C |
| | | (OKUNO CHEMICAL INDUSTRIES CO., LTD.) 40 ml/L, |
| | | CONCENTRATED HYDROCHLORIC ACID 150 ml/L |
| | TEMPERATURE: | 25° C. |
| | IMMERSION TIME: | 3 MINUTES |
| ACTIVATION | CHEMICAL: | CONCENTRATED SULFURIC ACID 100 ml/L |
| | TEMPERATURE: | 30° C. |
| | IMMERSION TIME: | 2 MINUTES |
| ELECTROLESS Ni | CHEMICALS: | TMP CHEMICAL NICKEL BATH |
| PLATING | | (OKUNO CHEMICAL INDUSTRIES CO., LTD.) pH 8-9.5 |
| | TEMPERATURE: | 30° C. |
| | IMMERSION TIME: | 10 MINUTES |

TABLE 5

| | | |
|---|---|---|
| SILICATIZING FLAME | FUEL GAS: | TETRAMETHYLSILANE AND TETRAMETHOXYSILANE |
| (PLUS OXIDIZING FLAME) | | (1% OR LESS CONTAINED IN PROPANE GAS) |
| | FLAME TEMPERATURE: | 1300° C. |
| | TREATMENT TIME: | 0.5 sec |
| VACUUM DEPOSITION | DEPOSITION METAL: | INDIUM |
| | DEGREE OF VACUUM: | 5.0 × 10⁻⁴ Pa |
| | DEPOSITION RATE: | 0.3-0.5 nm/sec |
| | FILM THICKNESS: | approx. 1000 Å |

What is claimed is:

1. A resin product with a plating film comprising:
a resin base material subjected to a surface modification treatment by blowing one of a silicatizing flame, a titanium oxidizing flame, and an aluminum oxidizing flame onto a surface of a resin base material; and
a plating film formed on the surface of the resin base material after the surface modification treatment, by performing one of dry plating and wet plating.

2. The resin product according to claim 1, wherein silanol groups are imparted to the surface of the resin base material.

3. The resin product according to claim 1, wherein said resin base material includes ABS resin.

4. The resin product according to claim 1, wherein said resin base material includes polypropylene resin.

5. A method of manufacturing a resin product with a plating film, comprising the steps of:
subjecting a resin base material to a surface modification treatment by blowing one of a silicatizing flame, a titanium oxidizing flame, and an aluminum oxidizing flame onto a surface of a resin base material; and
forming a plating film on the surface of the resin base material by performing one of dry plating and wet plating.

6. The method of manufacturing a resin product with a plating film according to claim 5, wherein at least one group of silanol group, titanium hydroxide and aluminum hydroxide imparted to the surface of the resin base material by blowing one of the silicatizing flame, the titanium oxidizing flame, and the aluminum oxidizing flame onto the surface of the resin base material.

7. The method of manufacturing a resin product with a plating film according to claim 5, wherein the silicatizing flame, the titanium oxidizing flame, or the aluminum oxidizing flame is blown together with an oxidizing flame.

8. The method of manufacturing a resin product with a plating film according to claim 5, wherein the silicatizing flame, the titanium oxidizing flame, or the aluminum oxidizing flame is blown as an ensuing process after blowing an oxidizing flame separately.

9. The method of manufacturing a resin product with a plating film according to claim 5, wherein said plating film is formed on the surface of the resin base material by performing silver mirror reaction.

10. The method of manufacturing a resin product with a plating film according to claim 5, wherein said plating film is formed on the surface of the resin base material by performing electroless plating.

11. The method of manufacturing a resin product with a plating film according to claim 5, wherein said plating film is formed on the surface of the resin base material by performing vacuum deposition.

12. The method of manufacturing a resin product with a plating film according to claim 11, said vacuum deposition includes indium vacuum deposition.

13. A method of manufacturing a resin product with a plating film, comprising the steps of:
imparting at least one group of silanol group, titanium hydroxide and aluminum hydroxide to a surface of a resin base material; and
forming a plating film on the surface of the resin base material.

14. The method of manufacturing a resin product with a plating film according to claim 13, further comprising:
imparting a catalyst to the surface of the resin;
activating the surface of the resin; and
performing silver mirror reaction, thereby forming a silver plating film as said plating film.

15. The method of manufacturing a resin product with a plating film according to claim 13, wherein at least one group of silanol group, titanium hydroxide and aluminum hydroxide is imparted to the surface of the resin base material by blowing one of the silicatizing flame, the titanium oxidizing flame, and the aluminum oxidizing flame onto the surface of the resin base material.

16. The method of manufacturing a resin product with a plating film according to claim 13, further comprising:
performing a chrome etching to the surface of the resin base material;
performing an acid neutralization on the surface of the resin base material;
imparting a catalyst to the surface of the resin;
activating the surface of the resin; and
performing electroless nickel plating, thereby forming a nickel plating film as said plating film.

17. The method of manufacturing a resin product with a plating film according to claim 16, wherein at least one group of silanol group, titanium hydroxide and aluminum hydroxide is imparted to the surface of the resin base material by blowing one of the silicatizing flame, the titanium oxidizing flame, and the aluminum oxidizing flame onto the surface of the resin base material.

18. The method of manufacturing a resin product with a plating film according to claim 13, further comprising:
performing vacuum deposition on the surface of the resin base material, thereby forming a plating film.

19. The method of manufacturing a resin product with a plating film according to claim 18, wherein at least one group of silanol group, titanium hydroxide and aluminum hydroxide is imparted to the surface of the resin base material by blowing one of the silicatizing flame, the titanium oxidizing flame, and the aluminum oxidizing flame onto the surface of the resin base material.

20. The method of manufacturing a resin product with a plating film according to claim 13, wherein said resin base material includes ABS resin.

21. The method of manufacturing a resin product with a plating film according to claim 13, wherein said resin base material includes polypropylene resin.
